(19) United States
(12) Patent Application Publication
(10) Pub. No.: US 2012/0204957 A1
(43) Pub. Date: Aug. 16, 2012

(54) METHOD FOR GROWING AlInGaN LAYER

(76) Inventors: David NICHOLLS, Oxford (GB); Tim Michael Smeeton, Oxford (GB); Valerie Berryman-Bousquet, Chipping Norton (GB); Stewart Edward Hooper, Oxford (GB)

(21) Appl. No.: 13/024,377

(22) Filed: Feb. 10, 2011

(51) Int. Cl. H01L 21/20; H01L 29/20; H01L 31/0304; H01L 33/32

(52) U.S. Cl. 136/262; 438/478; 257/103; 257/615; 257/E21.09; 257/E33.028; 257/E33.025; 257/E29.089; 257/E31.022

(57) ABSTRACT

A method for growing an In₍ₓ₎Al_{(y)}Ga_{(1-x-y)}N layer (where x is greater than zero and less than or equal to one, y is greater than or equal to zero and less than or equal to one and the sum of x and y is less than or equal to one). The method includes supplying plasma-activated nitrogen atoms as a source of nitrogen for the In₍ₓ₎Al_{(y)}Ga_{(1-x-y)}N layer to a growth surface, where a flux of the plasma-activated nitrogen atoms supplied to the growth surface is at least four times higher than a total flux of aluminium and gallium atoms also supplied to the growth surface, where either the aluminium or gallium flux may or may not be zero; and simultaneously supplying indium atoms and nitrogen-containing molecules to the growth surface.

### TECHNICAL FIELD

The invention relates to the growth of high-quality layers in semiconductor devices. In particular it relates to the growth of III-N material, containing indium, for opto-electronic or electronic applications.

### BACKGROUND ART

The III-V quaternary compound semiconductor, indium aluminium gallium nitride (hereinafter referred to as In₍ₓ₎Al_{(y)}Ga_{(1-x-y)}N, whereby x is greater than zero and less than or equal to one, y is greater than or equal to zero and less than or equal to one and the sum of x and y is less than or equal to one), is an important material due to the nature of its direct band-gap, which can be altered to span the entire visible range of the electromagnetic spectrum by varying the fractional contribution of the indium, aluminium and gallium that are present. This property makes In₍ₓ₎Al_{(y)}Ga_{(1-x-y)}N a suitable material for use in epitaxial opto-electronic devices where the wavelength of light that is emitted or absorbed is ideally in the visible range. Examples of such devices include light-emitting diodes, laser diodes and full-spectrum photovoltaic cells, for which there is increasing commercial demand.

Whilst there are distinct theoretical advantages to using In₍ₓ₎Al_{(y)}Ga_{(1-x-y)}N in a wide range of device applications, these advantages are not yet fully exploited because the existing methods used to grow the In₍ₓ₎Al_{(y)}Ga_{(1-x-y)}N, do not yield sufficiently high material quality. This is particularly the case for In₍ₓ₎Al_{(y)}Ga_{(1-x-y)}N with indium fraction of x>0.2. Growth of In₍ₓ₎Al_{(y)}Ga_{(1-x-y)}N materials with an aluminium fraction of y=0, hereinafter referred to as In₍ₓ₎Ga₍₁₋ₓ₎N, and with a range of indium fractions (x) have been very widely studied in the prior art. These results in the prior art provide a good example of the broader behaviour of the In₍ₓ₎Al_{(y)}Ga_{(1-x-y)}N material system with different indium fractions.

Materials in the III-N system are commonly grown by a variety of methods, including metal-organic chemical-vapour deposition (MOCVD) and molecular-beam epitaxy (MBE). The quality of the In₍ₓ₎Ga₍₁₋ₓ₎N layers grown using these techniques tends to be lower when the indium fraction (x) is higher. This has a significant impact on the efficiency of light emitting diodes (LEDs) which have In₍ₓ₎Ga₍₁₋ₓ₎N light-emitting active layers. LEDs with In₍ₓ₎Ga₍₁₋ₓ₎N light-emitting active layers can be fabricated to emit light at any wavelength in the visible spectrum, depending on the indium fraction in the active layers. For example, LEDs that emit blue light (emission wavelength approximately 450 nm) typically have In₍ₓ₎Ga₍₁₋ₓ₎N active layers with indium fractions between 0.15 and 0.20. LEDs that emit green light (emission wavelength approximately 520 nm) typically have In₍ₓ₎Ga₍₁₋ₓ₎N active layers with indium fractions between 0.20 and 0.30). And LEDs that emit yellow or red light (emission wavelength between approximately 600 nm and 800 nm) typically have indium fractions between 0.25 and 0.5). The wall plug efficiency of green LEDs tends to be much lower than the wall plug efficiency of blue LEDs. The wall plug efficiency of yellow and red LEDs tends to be much lower than the wall plug efficiency of green LEDs. The lower wall plug efficiencies of In₍ₓ₎Ga₍₁₋ₓ₎N LEDs with longer emission wavelengths are significantly due to lower material quality of the In₍ₓ₎Ga₍₁₋ₓ₎N active layers.

In particular, the quality of In₍ₓ₎Ga₍₁₋ₓ₎N layers in the prior art tends to degrade significantly for indium fractions (x) higher than about 0.2. The low quality of these layers also inhibits the efficiency of, or prevents the fabrication of, In₍ₓ₎Ga₍₁₋ₓ₎N laser diodes with longer emission wavelengths, such as green, yellow and red laser diodes. The low quality of the layers also inhibits the efficiency of photovoltaic cells (also known as solar cells) that have In₍ₓ₎Ga₍₁₋ₓ₎N active layers. In order to work efficiently, such In₍ₓ₎Ga₍₁₋ₓ₎N based solar cells must absorb as much light from the solar spectrum as possible, and convert it in to useable electrical current. The problem is similar to that of LEDs; indeed, in order to efficiently absorb and convert solar radiation of longer wavelengths to useable electrical current, the quality of the narrower band-gap layers (i.e. those containing higher indium fractions), must be higher than is typically seen in the prior art. As with LEDs, when the indium fractions exceed 0.20, there is a degradation in the quality of the material which leads to less efficient extraction of electrical carriers and hence makes the solar cell more inefficient.

The lower material quality of In₍ₓ₎Ga₍₁₋ₓ₎N with higher indium fractions is due to a combination of factors which are well documented in the prior art. The main factors which cause lower quality for higher indium fractions are the apparent necessity to use lower growth temperatures to grow the In₍ₓ₎Ga₍₁₋ₓ₎N layers, the presence of crystal defects caused by the increasing mismatch in lattice parameter between the In₍ₓ₎Ga₍₁₋ₓ₎N layer and the layer it is grown on (typically relaxed GaN) and the increased likelihood of phase separation in the In₍ₓ₎Ga₍₁₋ₓ₎N alloy.

The apparent necessity to use relatively low growth temperatures to grow In₍ₓ₎Ga₍₁₋ₓ₎N layers with high indium fractions is particularly important. It arises from a tendency for indium to desorb from the surface of the In₍ₓ₎Ga₍₁₋ₓ₎N layer during growth. This desorption of indium reduces the amount of indium which is incorporated into the resulting In₍ₓ₎Ga₍₁₋ₓ₎N layer. The magnitude of desorption can be conveniently quantified by the indium sticking factor. The indium sticking factor is the percentage of indium atoms that impinge on the substrate surface during growth which are incorporated in the resulting In₍ₓ₎Ga₍₁₋ₓ₎N layer.

The indium-sticking factor is related to the temperature of the growth surface. When the temperature of the growth surface increases, the rate of indium desorption increases and so the indium sticking factor decreases. The practical consequence of this behaviour is that in the prior art it has been necessary to use relatively low temperatures for In₍ₓ₎Ga₍₁₋ₓ₎N growth. Typically In₍ₓ₎Ga₍₁₋ₓ₎N growth temperatures are less than 800° C. for MOCVD growth and less than 650° C. for MBE growth. These temperatures are significantly lower than the temperatures of around 1000° C. that would be used for high-quality growth of other III-nitride materials such as GaN. Furthermore, as the desired indium fraction in the In₍ₓ₎Ga₍₁₋ₓ₎N layer increases, the maximum useable growth temperature decreases further. Use of low growth temperatures generally results in lower quality material due to several factors, such as increased incorporation of point defects, for example lattice vacancies or impurity atoms, into the growing In₍ₓ₎Ga₍₁₋ₓ₎N crystal.

One technique for growing In₍ₓ₎Al_{(y)}Ga_{(1-x-y)}N uses ammonia gas (NH₃). Ammonia can be used as the source of nitrogen for growth both by MBE and by MOCVD. The ammonia is thermally cracked at the substrate surface, owing to the high temperature of the substrate. The cracking of the ammonia molecule releases active nitrogen, that is nitrogen that can then be incorporated into the growing In₍ₓ₎Al_{(y)}Ga_{(1-x-y)}N layer. The efficiency of the cracking of ammonia increases as the substrate temperature is increased. The efficiency of ammonia cracking is low at the temperatures that are used for In₍ₓ₎Ga₍₁₋ₓ₎N growth and this further contributes to relatively poor material quality of these layers. For In(x) Al(y)Ga(1−x−y)N growth using ammonia, a compromise must be made between the high temperatures preferable for high ammonia cracking efficiency and high material quality, and the low temperatures required to achieve high indium fractions. Material quality for In₍ₓ₎Ga₍₁₋ₓ₎N with indium fractions of 0.2, which would correspond to blue/green emitting material, and higher indium fractions, are relatively poor. This is a well-known problem that is described in the prior art (e.g. Keller et al, Growth and characterization of N-polar InGaN/GaN multiquantum wells, Appl. Phys. Lett., 90, 191908 (2007)).

An alternative technique used to supply nitrogen when growing In₍ₓ₎Al_{(y)}Ga_{(1-x-y)}N utilizes a plasma source, where molecules containing nitrogen (for example nitrogen gas (N₂) molecules) are dissociated to release active nitrogen atoms (for example by using a radio-frequency (RF) plasma cell), which are directed towards the substrate and are able to form bonds with group III species substantially independently of the substrate temperature. When this method is used for MBE growth it is commonly referred to as PAMBE (plasma-assisted MBE). In contrast to growth using ammonia, the amount of active nitrogen is less strongly dependent on the substrate temperature. However, the indium-sticking factor is relatively low unless low growth temperatures are used (e.g. Okamoto et al, Effects of Atomic Hydrogen on the Indium Incorporation in InGaN Grown by RF-Molecular Beam Epitaxy, Jpn. J. Appl. Phys. 39(Pt. 2, 4b) L343, (2000)). Therefore, low growth temperatures must be used to achieve high levels of incorporation of indium in the grown In₍ₓ₎Ga₍₁₋ₓ₎N layer (e.g. x>0.2). The low temperatures required for this do not result in In₍ₓ₎Ga₍₁₋ₓ₎N with high material quality.

Growth of material at higher temperatures, by all known techniques, is desirable in order to achieve higher quality In₍ₓ₎Al_{(y)}Ga_{(1-x-y)}N. In order to produce better quality In₍ₓ₎Al_{(y)}Ga_{(1-x-y)}N with high indium fractions, a new method is needed that enables its growth at higher temperatures without increasing indium desorption.

There are no reports in the prior art of methods to significantly increase the sticking factor whilst maintaining high-quality two-dimensional growth. It has previously been shown in a MBE study by O'Steen et al, Effect of substrate temperature and V/III flux ratio on In incorporation for InGaN/GaN heterostructures grown by plasma-assisted molecular-beam epitaxy, Appl. Phys. Lett. 75(15), 2280, (11 Oct. 1999), that small increases in the indium sticking factor can be made by changing the (nitrogen)/(gallium flux) ratio during MBE growth with a RF plasma source of nitrogen. In this work the (nitrogen)/(gallium) was varied by small amounts in the range 0.9 to 1.1. These changes led to modest increases in the indium sticking factor when this ratio was varied by the largest extreme of the range, yielding an average superlattice indium composition increase from x=0.002 to x=0.009 at 675° C.

It is commonly written in the prior art that for growth of III-nitride material using RF plasma nitrogen sources the (active nitrogen)/(gallium flux) ratio must be close to 1.0 to obtain high quality material. This ratio is always maintained in the range between 0.8 and 1.2. It is generally found that significantly decreasing or increasing the value of this ratio leads to the production of poor quality material (material that contains a high number of defects and/or that is three-dimensional, i.e. material that is not suitable for efficient opto-electronic applications (e.g. Zywietz et al, Adatom diffusion at GaN (0001) and (0001) surfaces, Appl. Phys. Lett., 73 (4) 487 (27 Jul. 1998), and Koblmuller et al, High electron mobility GaN grown under N-rich conditions by plasma-assisted molecular beam epitaxy, Appl. Phys. Lett., 91, 221905 (2007))).

It would therefore appear that the method of O′Steen et al. is unsuitable to give the significant increases in indium-sticking factor that are necessary to produce high-indium content In₍ₓ₎Ga₍₁₋ₓ₎N at higher temperatures, because the (nitrogen)/(gallium) ratio should not be increased significantly above 1.0.

The indium-sticking factor can be increased by reducing the growth temperature. lliopoulos et al., InGaN(0001) alloys grown in the entire composition range by plasma assisted molecular beam epitaxy (Physica Status Solidi (a) 203 pp 102-105 (2006)) report sticking factors approaching 100% through use of exceptionally low temperatures (˜435° C.). However, the quality of In₍ₓ₎Ga₍₁₋ₓ₎N layers grown at these very low temperatures is not sufficiently high for use in optoelectronic or photovoltaic devices.

Bottcher et al, Incorporation of indium during molecular beam epitaxy of InGaN, Appl. Phys. Lett, 73 (22), 3232 (30 Nov. 1998), shows a typical example of the indium sticking factor percentage at 650° C., by PAMBE, to be 16%. This sticking coefficient decreases when the indium fraction in the In₍ₓ₎Ga₍₁₋ₓ₎N layer becomes higher than x=0.2.

For MBE, typically the source of nitrogen is either ammonia or active nitrogen from a plasma source, but not usually a combination of the two. Nevertheless, there exist examples in the prior art of single epitaxial devices containing layers grown by both techniques, thereby taking advantage of the respective qualities of each individual method (e.g. Tang et al, Effect of template morphology on the efficiency of InGaN/GaN quantum wells and light emitting diodes grown by molecular-beam epitaxy, Appl. Phys. Lett., 86, 121110 (2005) where In₍ₓ₎Ga₍₁₋ₓ₎N quantum wells are grown by PAMBE on top of GaN grown by NH₃-MBE). In addition, the potential to use a simultaneous supply of both in order to grow an active region in a MBE-grown device is described in patent application US20090256165A1: ‘Method of growing an active region in a semiconductor device using molecular beam epitaxy’ by Smith et al., published Oct. 15, 2009.

### SUMMARY OF INVENTION

This invention is a method to grow In₍ₓ₎Al_{(y)}Ga_{(1-x-y)}N layers that have high material quality and are suitable for use in electronic, optoelectronic and photovoltaic devices. The invention is particularly beneficial for In₍ₓ₎Al_{(y)}Ga_{(1-x-y)}N with indium fractions (x) larger than 0.2 including, as an example, In₍ₓ₎Ga₍₁₋ₓ₎N with indium fractions (x) larger than 0.2 (up to and including InN (x=1.0)). The invention provides a method to grow In₍ₓ₎Al_{(y)}Ga_{(1-x-y)}N with significantly higher growth temperatures than are used in the prior art. The method includes growing the In₍ₓ₎Al_{(y)}Ga_{(1-x-y)}N layer using plasma-activated nitrogen atoms as a source of nitrogen for the growing layer such that the flux of plasma-activated nitrogen atoms supplied to the growth surface is at least four times higher than the total flux of aluminium and gallium atoms supplied to the growth surface (the flux of either aluminium or gallium atoms may be zero) and such that there is a simultaneous supply of indium atoms and nitrogen-containing molecules to the growth surface. Preferably the flux of plasma-activated nitrogen atoms supplied to the growth surface is at least six times higher than the total flux of aluminium and gallium atoms supplied to the growth surface.

In accordance with an aspect of the invention, a method is provided for growing an In₍ₓ₎Al_{(y)}Ga_{(1-x-y)}N layer (where x is greater than zero and less than or equal to one, y is greater than or equal to zero and less than or equal to one and the sum of x and y is less than or equal to one). The method includes supplying plasma-activated nitrogen atoms as a source of nitrogen for the In₍ₓ₎Al_{(y)}Ga_{(1-x-y)}N layer to a growth surface, where a flux of the plasma-activated nitrogen atoms supplied to the growth surface is at least four times higher than a total flux of aluminium and gallium atoms also supplied to the growth surface, where either the aluminium or gallium flux may or may not be zero; and simultaneously supplying indium atoms and nitrogen-containing molecules to the growth surface.

In accordance with another aspect, a ratio of the plasma-activated nitrogen flux to the total flux of aluminium and gallium is at least 6.

According to another aspect, a ratio of the plasma-activated nitrogen flux to the total flux of aluminium and gallium is at least 10.

According to another aspect, a ratio of the plasma-activated nitrogen flux to the total flux of aluminium and gallium is at least 20.

In accordance with another aspect, a ratio of the plasma-activated nitrogen flux to the total flux of aluminium and gallium is at least 100.

In yet another aspect, the indium fraction (x) in the In₍ₓ₎Al_{(y)}Ga_{(1-x-y)}N layer is larger than 0.2.

According to another aspect, the indium fraction (x) in the In₍ₓ₎Al_{(y)}Ga_{(1-x-y)}N layer is larger than 0.5.

In accordance with still another aspect, the indium fraction (x) in the In₍ₓ₎Al_{(y)}Ga_{(1-x-y)}N layer is 1.0.

According to yet another aspect, the In₍ₓ₎Al_{(y)}Ga_{(1-x-y)}N layer is grown in a two-dimensional growth mode.

In accordance with still another aspect, the method utilizes molecular-beam epitaxy (MBE).

In still another aspect, the method utilizes metalorganic chemical vapour deposition (MOCVD).

In accordance with yet another aspect, the method utilizes remote-plasma chemical vapour deposition (RPCVD).

According to still another aspect, the method has an indium sticking factor higher than 50%.

According to still another aspect, the nitrogen-containing molecules are exclusively ammonia.

With still another aspect, the nitrogen containing molecules comprise a mixture of ammonia and N₂.

In still another aspect, the method uses a growth temperature greater than 600° C.

According to another aspect, the method uses a growth temperature greater than 800° C.

In accordance with still another aspect, the gallium atoms, indium atoms and/or aluminium atoms are supplied as components of molecules which dissociate at or near to the growth surface such that the gallium atoms, indium atoms and/or aluminium atoms can be incorporated in the In₍ₓ₎Al_{(y)}Ga_{(1-x-y)}N layer.

According to another aspect, the aluminium fraction (y) is zero.

In accordance with another aspect, x+y=1.

According to another aspect, an optoelectronic device is provided including an In₍ₓ₎Al_{(y)}Ga_{(1-x-y)}N layer grown in accordance with the method described herein, as a light-emitting region.

According to still another aspect, a photovoltaic device is provided including an In₍ₓ₎Al_{(y)}Ga_{(1-x-y)}N layer grown in accordance with the method described herein, as a light-absorbing region.

According to yet another aspect, an electronic device is provided including an In₍ₓ₎Al_{(y)}Ga_{(1-x-y)}N layer grown in accordance with the method described herein.

According to yet another aspect, a device is provided wherein x=1 and y=0.

To the accomplishment of the foregoing and related ends, the invention, then, comprises the features hereinafter fully described and particularly pointed out in the claims. The following description and the annexed drawings set forth in detail certain illustrative embodiments of the invention. These embodiments are indicative, however, of but a few of the various ways in which the principles of the invention may be employed. Other objects, advantages and novel features of the invention will become apparent from the following detailed description of the invention when considered in conjunction with the drawings.

### BRIEF DESCRIPTION OF DRAWINGS

In the annexed drawings, like references indicate like parts or features:

FIG. 1 shows the indium fraction (top graph) and indium sticking factor percentage (bottom graph) versus substrate temperature for a sample grown using this invention compared with the prior art.

FIG. 2 is a graph illustrating the electroluminescence intensity versus wavelength for light-emitting diodes grown under different conditions.

FIG. 3 is a plot of the indium fraction (x) in a series of In₍ₓ₎Ga₍₁₋ₓ₎N layers grown using different ratios between the plasma-activated nitrogen flux and the gallium flux.

FIG. 4 is a graph showing indium-sticking factor percentage as a function of V/III ratio (or, equivalently, plasma power) for quantum wells with an indium fraction of approximately x=0.20.

FIG. 5 shows a schematic diagram of a typical device structure containing layers grown using this invention.

### DETAILED DESCRIPTION OF INVENTION

This invention is a method to grow In₍ₓ₎Al_{(y)}Ga_{(1-x-y)}N layers that have high material quality and are suitable for use in electronic, optoelectronic and photovoltaic devices. The invention is particularly beneficial for In₍ₓ₎ Al_{(y)}Ga_{(1-x-y)}N with indium fractions (x) larger than 0.2. As an example, the invention is particularly beneficial for In₍ₓ₎Ga₍₁₋ₓ₎N (In₍ₓ₎Al_{(y)}Ga_{(1-x-y)}N with aluminium fraction of y=0) layers with indium fractions (x) larger than 0.2 and can also be beneficial for significantly higher indium fractions, up to and including 1.0 (InN), for which similar growth problems are encountered and can be addressed. The invention provides a method to grow In₍ₓ₎Al_{(y)}Ga_{(1-x-y)}N with significantly higher growth temperatures than are used in the prior art.

The invention will be described for the case of growth of In₍ₓ₎Ga₍₁₋ₓ₎N (In₍ₓ₎Al_{(y)}Ga_{(1-x-y)}N with aluminium fraction of y=0) grown using molecular beam epitaxy (MBE). However, the invention is also applicable to growth by any method where plasma-activated nitrogen atoms are used as a source of nitrogen for growing the In₍ₓ₎Al_{(y)}Ga_{(1-x-y)}N layer.

The method includes growing the In₍ₓ₎Al_{(y)}Ga_{(1-x-y)}N layer using plasma-activated nitrogen atoms as a source of nitrogen for the growing layer such that the flux of plasma-activated nitrogen atoms supplied to the growth surface is at least four times higher than the total flux of gallium and aluminium atoms also supplied to the growth surface and where there is a simultaneous supply of indium atoms and nitrogen-containing molecules to the growth surface. The flux of either the gallium or aluminium atoms may or may not be zero.

Preferably the flux of plasma-activated nitrogen atoms supplied to the growth surface is at least six times higher than the total flux of gallium and aluminium atoms supplied to the growth surface.

The flux of atoms is defined as the number of atoms reaching the growth surface per unit of area and per unit of time.

The gallium, aluminium and indium atoms may reach the growth surface as individual atoms that can be incorporated onto crystal lattice sites of the growing In₍ₓ₎Al_{(y)}Ga_{(1-x-y)}N layer. Alternatively, the gallium, aluminium and indium atoms may reach the growth surface as components of molecules where these molecules dissociate at, or near to, the growth surface such that the gallium, aluminium and indium atoms can be incorporated onto crystal lattice sites of the growing In₍ₓ₎Al_{(y)}Ga_{(1-x-y)}N layer.

A plasma-activated nitrogen atom is any nitrogen atom that reaches the growth surface with sufficient energy to be incorporated as a nitrogen atom onto crystal lattice sites of the growing In₍ₓ₎Al_{(y)}Ga_{(1-x-y)}N layer. As a first example, a plasma-activated nitrogen atom may be an individual nitrogen atom with positive electronic charge or negative electronic charge or no overall electronic charge. As a second example, a plasma-activated nitrogen atom may be an individual nitrogen atom that has been elevated to an electronically excited state by the plasma. As a third example, a plasma-activated nitrogen atom may be one or both of the two atoms in a nitrogen molecule (N₂) that has been elevated to an electronically excited state by the plasma. The previously listed examples are just a few of a wide range of possible types of plasma-activated nitrogen atoms.

Any nitrogen atom that reaches the growth surface with insufficient energy to be incorporated as a nitrogen atom onto a crystal lattice site of the growing In₍ₓ₎Al_{(y)}Ga_{(1-x-y)}N layer would not be classified as a plasma-activated nitrogen atom. For example, a nitrogen molecule (N₂) in its ground state (that is a nitrogen molecule with no electronic excitation) would not contain plasma-activated nitrogen atoms.

Plasma-activated nitrogen atoms may be generated by several methods. As a first example, plasma-activated nitrogen atoms may be generated by passing a flow of nitrogen gas (N₂) through a radio-frequency (RF) plasma source. An example of a suitable RF plasma source is a “Unibulb” RF-plasma source manufactured by Veeco Instruments. As a second example, plasma-activated nitrogen may be generated by passing a flow of nitrogen gas (N₂) through an electron cyclotron resonance (ECR) plasma source. As a third example, plasma-activated nitrogen may be generated by passing a flow of ammonia gas (NH₃) through a RF plasma source. The previously listed examples are just a few of a wide range of possible methods to generate plasma-activate nitrogen atoms.

The relative flux of gallium and plasma-activated nitrogen atoms can be conveniently measured by determining the “stoichiometric” condition where the flux of gallium atoms and plasma-activated nitrogen atoms are the same. If GaN is grown at relatively low temperature (e.g. ˜700° C. for MBE growth), such that desorption of gallium is negligibly small, an excess of gallium (for example droplets of gallium metal) will form on the growth surface when the flux of gallium is higher than the flux of plasma-activated nitrogen. The relative fluxes of gallium and plasma-activated nitrogen are equal for the highest gallium flux that does not lead to gallium droplet formation.

The nitrogen-containing molecules that are supplied to the growth surface can be any molecules that contain at least one nitrogen atom. Examples of suitable nitrogen-containing molecules are ammonia (NH₃), hydrazine (N₂H₄), dimethylhydrazine (C₂H₈N₂), phenylhydrazine (C₆H₈N₂), tertiarybutylamine (C₄H₁₁N), isopropylamine (C₃H₉N), hydrogen azide (HN₃₎and ethylenediamine (C₂N₂H₈). Either one type of molecule can be used exclusively (e.g., ammonia alone), or a mixture of different types of molecule may be used.

One exception is that the nitrogen-containing molecules supplied to the growth surface preferably are not exclusively nitrogen gas (N₂) molecules. The inventors have found, through experimentation, that if nitrogen gas (N₂) molecules are the only nitrogen-containing molecules that are supplied to the surface, then this method does not yield as high a quality In₍ₓ₎Al_{(y)}Ga_{(1-x-y)}N material.

It is preferred that the nitrogen-containing molecules supplied to the growth surface are a mixture of ammonia molecules (NH₃₎and nitrogen gas molecules (N₂).

It is preferred that the In₍ₓ₎Al_{(y)}Ga_{(1-x-y)}N layer grows in a two-dimensional (2D) growth mode, such that the growth surface remains substantially flat throughout growth.

The advantages of the invention will now be described by comparing experimental results for In₍ₓ₎Ga₍₁₋ₓ₎N layers grown by MBE using a method from the prior art and grown using this invention.

For the growth of In₍ₓ₎Ga₍₁₋ₓ₎N using plasma-assisted MBE (PAMBE) as described in the prior art, the substrate is heated and fluxes of gallium and indium atoms and plasma-activated nitrogen are incident on the substrate. Typically the substrate is a GaN surface (for example a GaN layer grown on a sapphire substrate), the gallium and indium fluxes are generated by elemental effusion cells, and the plasma-activated nitrogen is generated by flowing nitrogen gas (N₂) through a radio-frequency plasma cell. High-quality flat layers of In₍ₓ₎Ga₍₁₋ₓ₎N are obtained only for growth using conditions close to stoichiometry, such that the flux of plasma-activated nitrogen is not significantly larger or significantly smaller than the flux of gallium and indium atoms that are incorporated into the film. Typically the ratio of the flux of plasma-activated nitrogen to the flux of gallium and indium atoms that are incorporated into the film should be between 0.8 and 1.2.

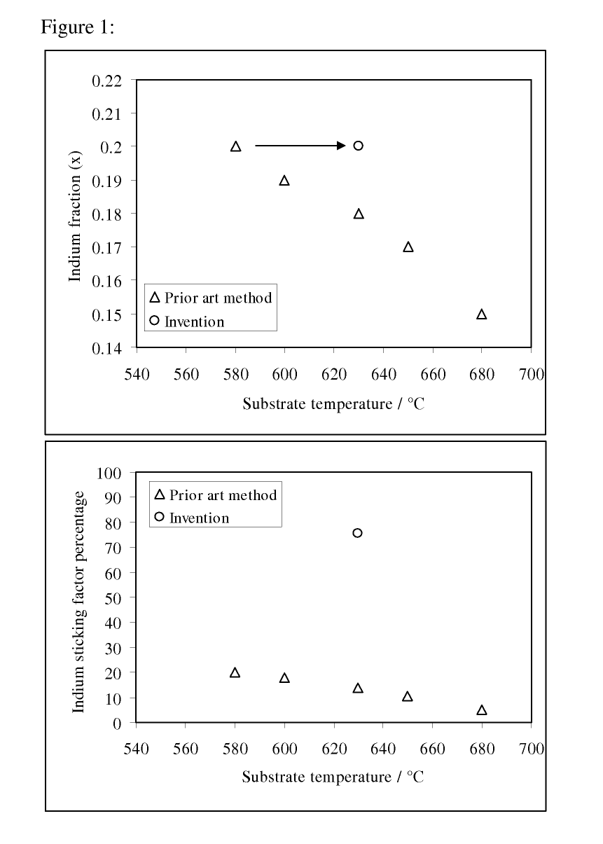

The inventors have extensively investigated the effect of gallium flux, indium flux, plasma-activated nitrogen flux and substrate temperature on the growth of In₍ₓ₎Ga₍₁₋ₓ₎N layers using methods in the prior art. From extensive experimental investigation of these parameters the inventors consistently observe that, for a particular growth temperature, there is a maximum indium fraction that can be obtained in a high-quality InₓGa₁₋ₓN layer. This behaviour is illustrated using the triangles in the plot in FIG. 1. At a growth temperature of 680° C. the highest indium fraction is x≈0.15. To obtain an indium fraction of xP≈0.20 the growth temperature must be reduced to 580° C. This reduction in growth temperature from 680° C. to 580° C. causes a very significant deterioration in the quality of the In₍ₓ₎Ga₍₁₋ₓ₎N layer. The In₍ₓ₎Ga₍₁₋ₓ₎N layer grown at the low temperature of 580° C. is not of sufficiently high quality for use in high-performance optoelectronic or photovoltaic devices. The apparent necessity to use lower growth temperatures to obtain higher indium fractions is commonly reported in the prior art.

The present invention overcomes this limitation. The circular data point in FIG. 1 shows the indium fraction obtained using the present invention. In this case the In_{0.20}Ga_{0.80}N layer was grown using a flux of plasma-activated nitrogen atoms approximately eight times higher than the flux of gallium atoms and with a simultaneous supply of indium atoms and nitrogen-containing molecules to the growth surface. Using this method an indium fraction of x=0.20 was obtained with a substrate temperature of 630° C. This method increases the viable growth temperature for In_{0.20}Ga_{0.80}N by 50° C. (from 580° C. to 630° C.), as shown by the arrow in FIG. 1. This use of a plasma-activated nitrogen flux eight times higher than the flux of gallium atoms is very significantly outside the normal range in the prior art for growth of a III-nitride material. Without the simultaneous supply of nitrogen-containing molecules, for example using ammonia (NH₃), to the growth surface such a high plasma-activated nitrogen flux results in highly three-dimensional growth and poor quality material.

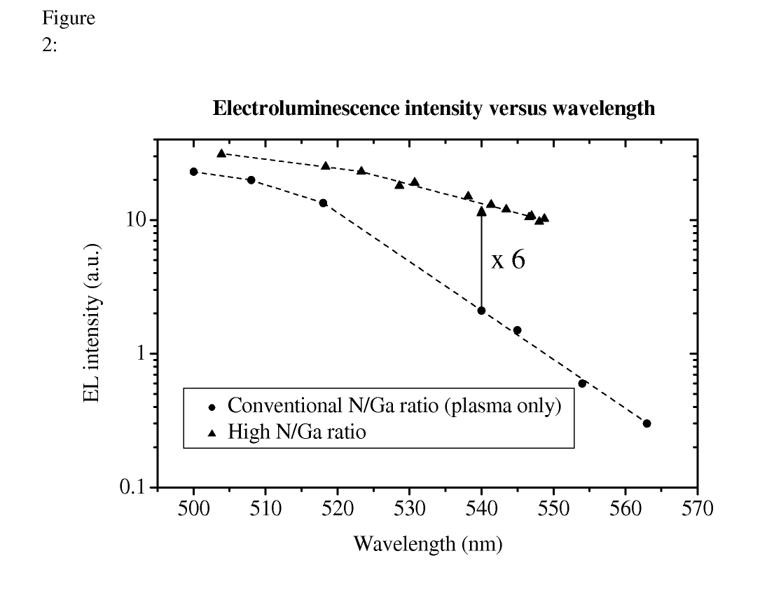

This invention can be used to significantly improve the quality of In₍ₓ₎Ga₍₁₋ₓ₎N layers and consequently to improve the performance of optoelectronic and photovoltaic device which contain the In₍ₓ₎Ga₍₁₋ₓ₎N layers. An example of this improvement in device performance is shown in FIG. 2. This plot shows the light-emission efficiency of two sets of LEDs that emit green light electroluminescence for an injection current density of 0.45 kAcm⁻². In both cases the light-emitting active region of the LEDs is a single In₍ₓ₎Ga₍₁₋ₓ₎N quantum well. The indium fraction in the In₍ₓ₎Ga₍₁₋ₓ₎N quantum wells is in the range between x=0.20 and x=0.25. For these devices, and these electrical injection conditions, a quantum well indium fraction of x=0.20 results in an emission wavelength of approximately 500 nm; as the indium fraction increases to 0.25 the emission wavelength increases to approximately 560 nm.

For the first set of LEDs (the lower data points (circles) in FIG. 2) the In₍ₓ₎Ga₍₁₋ₓ₎N quantum wells were grown using a carefully optimised version of the PAMBE method described in the prior art. These results represented the best electroluminescence results obtained after an extensive optimisation of the growth parameters, involving more than one hundred separate samples, to obtain the highest electroluminescence efficiency. The vertical scale in the plot uses a logarithmic scale. The electroluminescence of these devices is significantly lower for LEDs emitting longer wavelengths: the electroluminescence at 560 nm is approximately 100 times lower than the electroluminescence at 500 nm.

The second set of LEDs (the higher data points (triangles) in FIG. 2) used In₍ₓ₎Ga₍₁₋ₓ₎N active layers grown using the current invention. These In₍ₓ₎Ga₍₁₋ₓ₎N quantum wells were grown with a ratio of plasma-activated nitrogen flux to gallium flux of eight. The electroluminescence efficiency of these devices is significantly higher than the electroluminescence efficiency of the first set of LEDs fabricated using the In₍ₓ₎Ga₍₁₋ₓ₎N growth method in the prior art. At a wavelength of 540 nm the electroluminescence of the LEDs grown using this invention is six times higher than for LEDs grown using the method in the prior art (this six times increase is indicated using the arrow in FIG. 2).

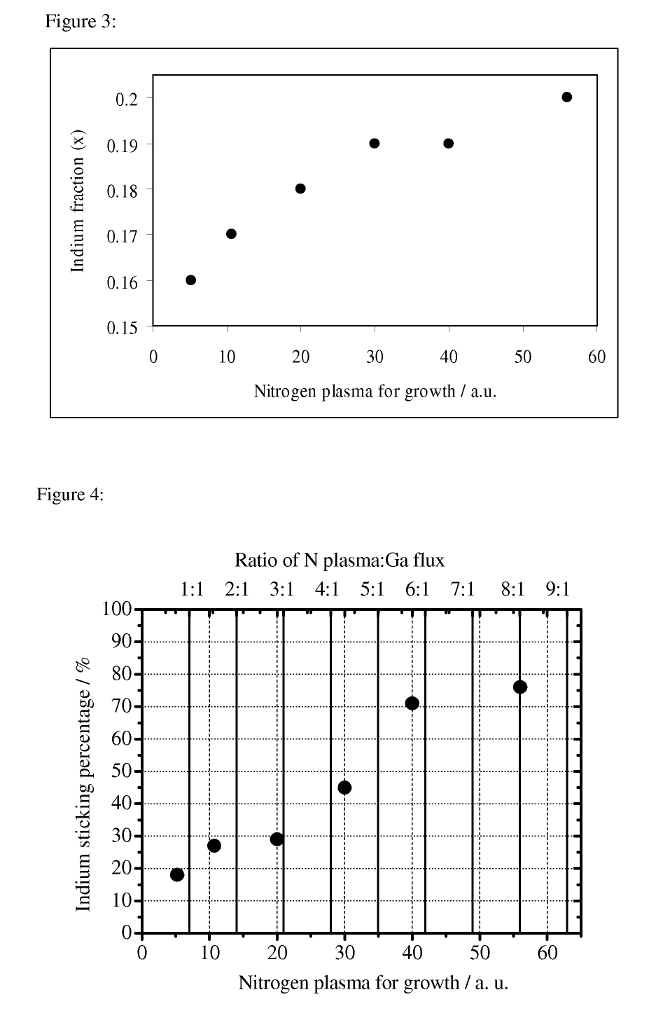

The advantages of using plasma-activated nitrogen flux significantly higher than the gallium flux are further explained using the results in FIGS. 3 and 4. FIG. 3 is a plot of the indium fraction (x) in a series of In₍ₓ₎Ga₍₁₋ₓ₎N layers grown using different ratios between the plasma-activated nitrogen flux and the gallium flux. FIG. 4 is a plot of the indium sticking factor percentage during growth of the same samples. The indium sticking factor percentage is calculated using carefully calibrated measurements of the flux of indium atoms impinging on the surface during growth and measurements of the indium fraction (x) in the resulting In₍ₓ₎Ga₍₁₋ₓ₎N layer.

All of these In₍ₓ₎Ga₍₁₋ₓ₎N layers were grown with a substrate temperature of 630° C. and with the same gallium flux. The In₍ₓ₎Ga₍₁₋ₓ₎N layers were grown as single quantum wells (with thickness of 2.5 nm) in the active region of LED structures. For each value of plasma-activated nitrogen flux a series of samples were grown with different indium fluxes during the In₍ₓ₎Ga₍₁₋ₓ₎N layer growth. The optimum indium flux was chosen according to the highest electroluminescence efficiency of the LEDs. The results in FIGS. 3 and 4 correspond to these optimum indium fluxes. FIG. 3 shows that, as the plasma-activated nitrogen flux is increased, the indium fraction in the In₍ₓ₎Ga₍₁₋ₓ₎N layers increases significantly. FIG. 4 shows that, as the plasma-activated nitrogen flux is increased, the indium sticking factor percentage increases significantly. Where lower values of plasma-activated nitrogen flux were used, sticking factors were more similar to the values seen in the prior art.

An indium sticking factor percentage higher than 50%, namely 75%, is obtained when the plasma-activated nitrogen flux is eight times higher than the gallium flux. This value of 75% is exceptionally high for growth of In₍ₓ₎Ga₍₁₋ₓ₎N at these temperatures (that is, at temperatures high enough to yield high material quality) and represents a large difference from the prior art.

Further increases in sticking factor, and therefore increases in viable In₍ₓ₎Ga₍₁₋ₓ₎N growth temperature, are achievable by using even higher fluxes of plasma-activated nitrogen such that the plasma-activated nitrogen flux is more than eight times the gallium flux.

The example of the invention given above is for growth of In₍ₓ₎Al_{(y)}Ga _{(1-x-y)}N with no aluminium flux and a resulting aluminium fraction of y=0. For In₍ₓ₎Al_{(y)}Ga _{(1-x-y)}N where the aluminium flux is not zero, the flux of plasma-activated nitrogen is maintained at a level at least four times the total flux of both aluminium and gallium atoms.

A typical embodiment of the method in this invention for fabrication of the light-emitting active region of an LED structure will now be described.

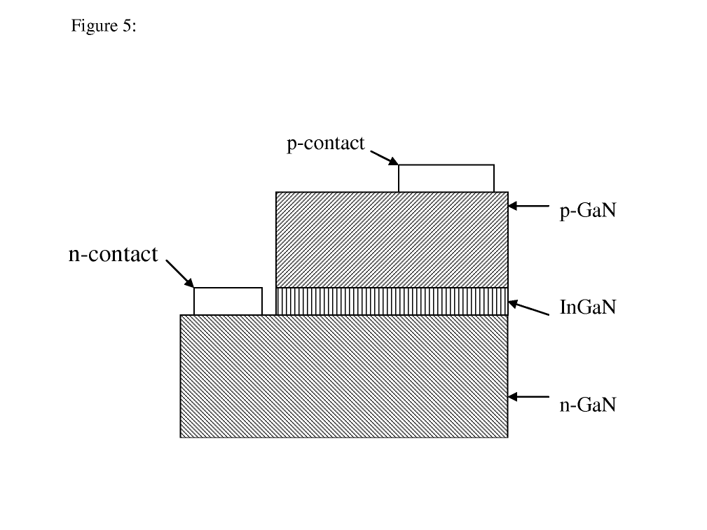

An example of a basic but typical structure containing layers grown with this invention is shown in FIG. 5, whereby an In₍ₓ₎Ga₍₁₋ₓ₎N layer is sandwiched between GaN layers, one of which is n-type doped, the other of which is p-type doped. The doped layers are subsequently contacted; the device can be adapted and elaborated for emitting or absorbing light, for example as an LED, laser diode or photovoltaic cell.

A suitable substrate is prepared for growth, by any conventional method, in a MBE machine. This will typically involve heating the substrate to high temperatures under vacuum conditions (for example, to 500° C. in a vacuum of <1×10⁻⁷ mbar) in order to remove any contaminants. Such out-gassing may then be performed at higher temperatures, although it may be necessary to supply material, for example ammonia, in order to suppress decomposition. The substrate is preferably freestanding single-crystal gallium nitride, or an epitaxial layer of gallium nitride on a suitable substrate, for example sapphire (this is commonly known as a GaN template and is commercially available). However, the substrate may be any layer upon which In₍ₓ₎Ga₍₁₋ₓ₎N is to be grown, be it a two-dimensional or three-dimensional surface. The substrate could be a single material, for example free-standing single-crystal gallium nitride, or an epitaxial layer, for example a gallium nitride template (whereby gallium nitride is grown on sapphire), or any other epitaxial layer grown in either the equipment used for the invention or any other equipment. Other examples of possible substrates include silicon, silicon carbide, magnesium oxide and zinc oxide. However, any material upon which the In₍ₓ₎Ga₍₁₋ₓ₎N is grown, be it a two-dimensional or three-dimensional surface and be it crystalline or amorphous, may have improved material resulting from the application of this invention. Indeed, it may be appropriate to first grow layers that precede the active In₍ₓ₎Ga₍₁₋ₓ₎N layer; for example, in a LED structure, it may be appropriate to grow a n-type doped region prior to the growth of the In₍ₓ₎Ga₍₁₋ₓ₎N. The layer is conventionally grown on epitaxial layers previously deposited in the MBE machine, however it can also be grown on layers that have been grown elsewhere, for example by MOCVD. The layer is ideally heated under a flow of ammonia; this is to prevent any decomposition of material that may occur due to high temperature and low-pressure conditions. It is known that, generally, if the temperature is significantly less than 800° C., decomposition will be minimal; nevertheless, it is considered prudent to follow the practice of heating and cooling the substrate under a flow of ammonia.

Once a suitable epitaxy-ready surface has been prepared, the substrate is heated to a suitable temperature for the growth of In₍ₓ₎Ga₍₁₋ₓ₎N with a given composition; in this case a temperature of 630° C. is used to obtaining high-quality material with an indium fraction of approximately x=0.2. The temperature can nevertheless be altered as desired in order to obtain improvements in the material. The layer is heated at a rate that is not so fast that there is non-uniform temperature distribution; this is to prevent any thermal stress that could be detrimental to the quality of the subsequent growth.

While the condition of the substrate and the sources of elemental gallium, indium are being prepared for growth, simultaneously a nitrogen plasma is formed, using a flow of N₂ gas through a Veeco Instruments Unibulb RF-plasma source with 506, 0.1 mm apertures.

Typical conditions would use a beam-equivalent pressure of nitrogen at approximately 1×10 ⁻⁴ mbar and plasma power of 500 W. Once the plasma and temperature of the substrate are stable, the sample is exposed to the plasma-activated from the RF plasma cell and simultaneously a flow of ammonia gas with a beam-equivalent pressure of 5×10 ⁻³ mbar and elemental gallium and elemental indium fluxes. These elements are introduced into the chamber using conventional effusion cells. The gallium flux is 2.5×10¹⁹ atoms m⁻²min⁻¹ and the indium flux is 8.3×10¹⁸ atoms m⁻²min⁻¹. These conditions yield a ratio of plasma-activated nitrogen flux to gallium flux of eight.

After a specified time, for example 4 minutes in the case of the production of a quantum well layer with thickness of approximately 3 nm, the nitrogen plasma, and indium cell are shuttered off from the chamber. The ammonia continues to flow towards the substrate; the gallium may continue to be directed towards the substrate in order to grow a thin GaN capping layer that is designed to suppress indium desorption. Aluminium may also be directed towards the substrate as per the structure that is to be grown. Subsequent layers can then be grown according to the nature of the device structure that is being sort, for example, in the case of an LED, a region that is p-type doped maybe be grown. There is no limit to the number of epitaxial layers that can be grown using this technique, nor to the thickness of these layers.

In the example given above, elemental gallium and indium were used, but alternatively the gallium and indium atoms could be supplied as metal-organic compounds, for example trimethyl gallium and trimethyl indium.

In the example given above the ratio of plasma-activated nitrogen flux to gallium flux was 8. Preferably this ratio would be higher than 8. For example, this ratio can be at least 10, at least 20, at least 50 or at least 100 to enable growth of In₍ₓ₎Ga₍₁₋ₓ₎N at higher temperatures or with higher indium fractions (x). When the ratio is at least 10, this method provides a powerful method to grow high-quality In₍ₓ₎Ga₍₁₋ₓ₎N with indium fractions (x) larger than 0.2. When the ratio is at least 20, this method provides a powerful method to grow high-quality In₍ₓ₎Ga₍₁₋ₓ₎N with indium fractions (x) larger than 0.3 and also larger than 0.5. These In₍ₓ₎Ga₍₁₋ₓ₎N layers are suitable for use as optically absorbing layers in photovoltaic cells.

In the broader case of growing an In₍ₓ₎Al_{(y)}Ga_{(1-x-y)}N layer, the ratio of plasma-activated nitrogen flux to the total flux of aluminium and gallium atoms supplied to the growth surface is at least 4 in accordance with the invention. Preferably this ratio would be at least 6 or higher. For example, this ratio can be at least 10, at least 20, at least 50 or at least 100 to enable growth of In₍ₓ₎Al_{(y)}Ga_{(1-x-y)}N at higher temperatures or with higher indium fractions (x). With the method of the present invention high quality In₍ₓ₎Al_{(y)}Ga_{(1-x-y)}N growth with indium fractions larger than 0.2, larger than 0.3, larger than 0.5, and equal to 1.0, for example, is achievable. The method may produce an indium sticking factor higher than 50%, and the nitrogen-containing molecules may be exclusively ammonia or a mixture of ammonia and N₂, for example. Gallium atoms, indium atoms and/or aluminium atoms may be supplied as components of molecules which dissociate at or near to the growth surface such that the gallium atoms, indium atoms and/or aluminium atoms can be incorporated in the In₍ₓ₎Al_{(y)}Ga_{(1-x-y)}N layer.

In order to obtain the higher ratios of plasma-activated nitrogen flux to total flux of aluminium and gallium atoms, it may be desirable to utilize two or more nitrogen plasma cells within the same epitaxial growth system. The outputs of the respective plasma cells may be combined to produce the desired higher ratios of plasma-activated nitrogen flux.

Although the description given above has referred to use of this invention for MBE growth, all aspects of the invention are also applicable to growth using other deposition methods where plasma-activated nitrogen can be used. Examples include metalorganic chemical vapour deposition (MOCVD) methods and remote-plasma chemical vapour deposition (RPCVD) methods. Viable growth temperatures for In₍ₓ₎Al_{(y)}Ga_{(1-x-y)}N using CVD methods are higher than the viable temperatures using MBE. Therefore, the preferred growth temperatures for MOCVD will be higher than in the example given above. However, the introduction of a flux of plasma-activated nitrogen with a ratio at least four times higher than the flux of gallium atoms still results in an increase in viable growth temperature and consequently and increase in material quality. Growth temperatures greater than 600° C., and even greater than 800° C., are therefore possible in accordance with the invention.

Although the invention has been shown and described with respect to a certain embodiment or embodiments, equivalent alterations and modifications may occur to others skilled in the art upon the reading and understanding of this specification and the annexed drawings. In particular regard to the various functions performed by the above described elements (components, assemblies, devices, compositions, etc.), the terms (including a reference to a “means”) used to describe such elements are intended to correspond, unless otherwise indicated, to any element which performs the specified function of the described element (i.e., that is functionally equivalent), even though not structurally equivalent to the disclosed structure which performs the function in the herein exemplary embodiment or embodiments of the invention. In addition, while a particular feature of the invention may have been described above with respect to only one or more of several embodiments, such feature may be combined with one or more other features of the other embodiments, as may be desired and advantageous for any given or particular application.

### INDUSTRIAL APPLICABILITY

A method to grow In₍ₓ₎Al_{(y)}Ga_{(1--y)}N layers that have high material quality and are suitable for use in electronic, optoelectronic and photovoltaic devices. Growth at higher temperatures without increasing indium desportion is possible.

1. A method for growing an Inₘ Al_{(y)}Ga_{(1-x-y)}N layer (where x is greater than zero and less than or equal to one, y is greater than or equal to zero and less than or equal to one and the sum of x and y is less than or equal to one), comprising:
supplying plasma-activated nitrogen atoms as a source of nitrogen for the In₍ₓ₎Al_{(y)}Ga_{(1-x-y)}N layer to a growth surface, where a flux of the plasma-activated nitrogen atoms supplied to the growth surface is at least four times higher than a total flux of aluminium and gallium atoms also supplied to the growth surface, where either the aluminium or gallium flux may or may not be zero; and
simultaneously supplying indium atoms and nitrogen-containing molecules to the growth surface.

2. The method according to claim 1, wherein a ratio of the plasma-activated nitrogen flux to the total flux of aluminium and gallium is at least 6.

3. The method according to claim 1, wherein a ratio of the plasma-activated nitrogen flux to the total flux of aluminium and gallium is at least 10.

4. The method according to claim 1, wherein a ratio of the plasma-activated nitrogen flux to the total flux of aluminium and gallium is at least 20.

5. The method according to claim 1, wherein a ratio of the plasma-activated nitrogen flux to the total flux of aluminium and gallium is at least 100.

6. The method according to claim 1, wherein the indium fraction (x) in the In₍ₓ₎Al_{(y)}Ga_{(1-x-y)}N layer is larger than 0.2.

7. The method according to claim 1, wherein the indium fraction (x) in the In₍ₓ₎Al_{(y)}Ga_{(1-x-y)}N layer is larger than 0.5.

8. The method according to claim 1, wherein the indium fraction (x) in the In₍ₓ₎Al_{(y)}Ga_{(1-x-y)}N layer is 1.0.

9. The method according to claim 1, wherein the In₍ₓ₎Al_{(y)}Ga_{(1-x-y)}N layer is grown in a two-dimensional growth mode.

10. The method according to claim 1, wherein the method utilizes molecular-beam epitaxy (MBE).

11. The method according to claim 1, wherein the method utilizes metalorganic chemical vapour deposition (MOCVD).

12. The method according to claim 1, wherein the method utilizes remote-plasma chemical vapour deposition (RPCVD).

13. The method according to claim 1, wherein the method has an indium sticking factor higher than 50%.

14. The method according to claim 1, wherein the nitrogen-containing molecules are exclusively ammonia.

15. The method according to claim 1, wherein the nitrogen containing molecules comprise a mixture of ammonia and N₂.

16. The method according to claim 1, utilizing a growth temperature greater than 600° C.

17. The method according to claim 1, utilizing a growth temperature greater than 800° C.

18. The method according to claim 1, wherein the gallium atoms, indium atoms and/or aluminium atoms are supplied as components of molecules which dissociate at or near to the growth surface such that the gallium atoms, indium atoms and/or aluminium atoms can be incorporated in the In₍ₓ₎Al_{(y)}Ga_{(1-x-y)}N layer.

19. The method according to claim 1, wherein the aluminium fraction (y) is zero.

20. The method according to claim 1, wherein x+y=1.

21. An optoelectronic device comprising an In₍ₓ₎Al_{(y)}Ga_{(1-x-y)}N layer grown in accordance with the method of claim 1, as a light-emitting region.

22. A photovoltaic device comprising an In₍ₓ₎Al_{(y)}Ga_{(1-x-y)}N layer grown in accordance with the method of claim 1, as a light-absorbing region.

23. An electronic device comprising an In₍ₓ₎Al_{(y)}Ga_{(1-x-y)}N layer grown in accordance with the method of claim 1.

24. The device according to claim 21, wherein x=1 and y=0.
